(19) United States
(12) Patent Application Publication
(10) Pub. No.: US 2016/0087129 A1
(43) Pub. Date: Mar. 24, 2016

(54) METHODS FOR ENGINEERING POLAR DISCONTINUITIES IN NON-CENTROSYMMETRIC HONEYCOMB LATTICES AND DEVICES INCLUDING A TWO-DIMENSIONAL INSULATING MATERIAL AND A POLAR DISCONTINUITY OF ELECTRIC POLARIZATION

(71) Applicant: ECOLE POLYTECHNIQUE FÉDÉRALE DE LAUSANNE (EPFL), Lausanne (CH)

(72) Inventors: Marco GIBERTINI, Lausanne (CH); Giovanni PIZZI, Lausanne (CH); Nicola MARZARI, Lausanne (CH)

(21) Appl. No.: 14/636,911

(22) Filed: Mar. 3, 2015

(30) Foreign Application Priority Data
Mar. 5, 2014 (IB) PCT/IB2014/059471
Jan. 12, 2015 (IB) PCT/IB2015/050221

(51) Int. Cl. H01L 31/0445; H01L 31/0304; H01L 31/18; H01L 31/068; H01L 31/0693; H01L 31/074; H01L 31/028; H01L 31/062

(52) U.S. Cl. CPC H01L 31/0445; H01L 31/028; H01L 31/03044; H01L 31/062; H01L 31/068; H01L 31/0693; H01L 31/074; H01L 31/18

(57) ABSTRACT

The present invention relates to a device comprising a two-dimensional component, the two-dimensional component including at least one two-dimensional insulating material and including a polar discontinuity of the electric polarization. The present invention also relates to methods for producing such a device.

### CROSS-REFERENCE TO RELATED APPLICATIONS

This application claims the benefit of International application PCT/IB2014/059471, filed Mar. 5, 2014 as well as of International application PCT/IB2015/050221, filed Jan. 12, 2015, the entire contents of which are incorporated herein by reference.

### FIELD OF THE INVENTION

The present invention concerns devices comprising a two-dimensional component, the two-dimensional component including at least one two-dimensional insulating material and a polar discontinuity of electric polarization. The present invention also relates to methods and different pathways to engineer polar discontinuities across interfaces between honeycomb lattices, for example. Three broad approaches are described, that are based on 1) finite strips of material (nanoribbons) where a polar discontinuity against the vacuum can emerge, 2) interfaces between different phases supporting distinct polarizations, and 3) functionalizations, where covalent ligands are used to engineer the polar properties and introduce polar discontinuities by selective or total functionalization of the parent system.

All the systems considered deliver innovative applications, for example, in ultra-thin and flexible solar-energy devices and in micro and nanoelectronics.

### BACKGROUND

Unprecedented and fascinating phenomena have been recently observed at oxide interfaces between centrosymmetric cubic materials, such as LaAlO₃ and SrTiO₃, where a polar discontinuity across the boundary gives rise to polarization charges and electric fields that drive a metal-insulator transition, with the appearance of free carriers at the interface. Two-dimensional analogues of these systems are possible, and non-centrosymmetric honeycomb lattices could offer a fertile playground, thanks to their versatility and the extensive on-going experimental efforts in graphene and related materials. As mentioned above, the present invention in particular relates to different realistic pathways to engineer polar discontinuities across interfaces between honeycomb lattices, and support for this invention is, for example, provided via extensive first-principles calculations. Three broad approaches are discussed, that are based on 1) finite strips of material (nanoribbons) where a polar discontinuity against the vacuum can emerge, 2) interfaces between different phases supporting distinct polarizations, and 3) functionalizations, where covalent ligands are used to engineer the polar properties and introduce polar discontinuities by selective or total functionalization of the parent system. All the systems considered deliver innovative applications in ultra-thin and flexible solar-energy devices and in micro and nanoelectronics.

Combining together different materials rarely results in a simple “arithmetic sum” of their properties. Typically, the composite system displays properties that were not present in its components, giving rise to new and unexpected behaviors. This is the case, for instance, of many semiconductor devices, which rely on the peculiar phenomena occurring at atomically-sharp interfaces between different semiconductors. More recently, oxide interfaces have been attracting considerable attention, both theoretically and experimentallyl^{1,2,3}. Among these, a dominant role is played by heterostructures of strontium titanate (SrTiO₃ or STO) and lanthanum aluminate (LaAlO₃ or LAO). Both LAO and STO are simple insulators but, when brought together, a two-dimensional electron gas (2DEG) with high mobility appears at their interface⁴. This 2DEG is host to a rich variety of interesting phenomena, ranging from superconductivity⁵ to magnetism⁶ (or even the unprecedented combination of the two^{7,8}), and is very promising for many device applications. The most intuitive picture to explain the existence of the 2DEG follows from the bulk properties of the constituent compounds. LAO and STO have a cubic centrosymmetric crystal structure. Therefore, classically, one would expect the macroscopic polarization of each material to be zero (owing to their inversion symmetry). However, in the framework of the Modern Theory of Polarization¹⁸, polarization cannot be represented by as a single vector, but rather as a lattice of vectors with the same periodicity of the crystal lattice and that has to be mapped onto itself by all the symmetries of the crystal. For cubic systems, this gives rise to two admissible realizations for the polarization lattice: one containing the zero vector, and another shifted by half of the cubic diagonal. First-principles simulations show that STO belongs to the first class, while LAO to the second^{10,11}, meaning that the two materials support a different electric polarization. As a result, a discontinuity in the electric polarization (which we will call hereafter polar discontinuity) appears when LAO is epitaxially grown on top of STO, and a polarization charge builds up at the interface. This creates an electric field inside LAO that in turn induces a linear shift in the energy bands of LAO. As the thickness of the LAO overlayer increases, the effective gap of the composite system decreases, up to a point at which the top of the valence band coincides in energy with the bottom of the conduction band and the system becomes metallic with a transfer of free charges from the surface of LAO to the STO/LAO interface. This metal-insulator transition as a function of the LAO thickness has been found experimentally to occur at 3-4 unit cells⁹, in agreement with theoretical calculations^{10,11}. In principle, by further increasing the thickness of the LAO film, a progressive charge transfer occurs until the free charge accumulated at the interface completely screens the polarization charge and the electric field inside LAO vanishes^{11,12}.

One may expect free carriers to appear at the boundary between two-dimensional (2D) insulating materials provided that their bulk polarizations are different. By 2D materials we mean crystals that are extended in two dimensions but restricted to one or few (≦5) monolayers along the third (e.g. graphene, a single layer of graphite). In this respect non-centrosymmetric honeycomb lattices offer an interesting playground owing to the quantized and topological nature of their bulk polarization^{13,14} (that in this system can assume three different values, rather than the two possible polarizations discussed above for cubic 3D crystals). In Ref 15 the authors considered interfaces between different heteroatomic crystals with an underlying honeycomb lattice: aluminum nitride (AlN), silicon carbide (SiC), and zinc oxide (ZnO). Although these materials do not exist as 2D hexagonal monolayers, it is possible to theoretically calculate their electronic properties. Simulations have revealed that indeed a polar discontinuity at the interface between two such honeycomb crystals gives rise to a metal-insulator transition, with a free charge accumulating on a one-dimensional (1D) channel along the interface. In the thermodynamic limit, the linear charge density λ_{F} of free carriers perfectly balances the polarization charge density λ_{P} and it is thus determined solely by the bulk properties of the materials involved and by the orientation of the interface through¹⁶

λ_{F}=(P₂−P₁)·\hat{n}₁₂=−λ_{P} (1)

Here P_{1,2} are the bulk polarizations of the parent crystals and \hat{n}₁₂ is a unit vector normal to the interface and pointing from 1 to 2. Although the very general idea of a 2D analogue of the LAO/STO interface is very promising, a practical concern hinders the feasibility of the setup of Ref 15: The realization of atomically-defined interfaces between perfectly aligned 2D crystals. Indeed, although lateral graphene/BN heterostructures have recently been reported¹⁷, the extension to other 2D materials seems to be beyond the current reach of experimental technology, especially because 2D monolayers of AlN, ZnO and SiC have never been synthetized.

### SUMMARY OF THE INVENTION

In the present invention we set out different approaches to the realization of a polar discontinuity at the interface between non-centrosymmetric honeycomb structures. First, we underline that vacuum can be interpreted as an insulator with vanishing polarization. As a consequence, by cutting any polar honeycomb lattice into a strip (also known as nanoribbon), polarization charges will appear at the edges (i.e., at the interface with vacuum). These create an electric field that drives a charge transfer and metal-insulator transition as a function of the system size. Second, we put forward that different phases (i.e. different crystal structures, as distinguished solely by their symmetries) of 2D crystals or materials like transition metal dichalcogenides can have distinct electric polarizations, so that interfaces between such phases support a polar discontinuity. Finally, we suggest that covalent functionalizations (for instance with hydrogen or fluorine) change the polarization of the parent crystal. Selective functionalization (as defined below) of a 2D sheet thus introduces a discontinuity in the electric polarization, giving rise to a finite electric field and to the appearance of 1D charge channels at the boundary between functionalized and pristine regions. We will now describe in more detail these strategies and their possible realizations, supporting our ideas with the results of first-principles numerical simulations. It is important to mention that, although we will focus on honeycomb lattices owing to their experimental relevance, there are other 2D systems in which polarization discontinuities could be engineered. Indeed, for many lattices with different point-groups, symmetry allows for several polarization states¹⁴. For instance, instead of three possible polarization values as in honeycomb lattices (see below), square lattices can assume two different quantized polarizations (similarly to what happens for cubic 3D crystals like LAO and STO). Thus a polar discontinuity would appear at the interface between square lattices with different polarization.

### BRIEF DESCRIPTION OF THE DRAWINGS

FIGS. 1(a), (b), (c), (d), and (e) illustrate possible realizations of polar discontinuity in honeycomb lattices, as further explained below.

FIGS. 2(a), (b), (c), and (d) illustrate Wannier function centers in honeycomb lattices, as further explained below.

FIGS. 3(a), (b), (c), and (d) illustrate numerical results for BN—BNH₂ interfaces.

FIGS. 4(a) and (b) illustrate possible nanoribbon terminations.

FIGS. 5(a) and (b) illustrate the macroscopic average (black lines) on top of the planar average (gray lines) of the electrostatic potential energy as a function of the in-plane coordinate orthogonal to the nanoribbon edges.

FIGS. 6(a) and (b) illustrate the band structure and Wannier functions of MoS₂.

FIGS. 7(a), (b), and (c) illustrate possible conformers of functionalized honeycomb lattices.

FIG. 8 illustrates a 1D channel of free carriers at the interface between two insulating materials with different polarization exploited to transfer a current signal from one device to another, exceeding the current limits of lithography.

FIGS. 9(a) and (b) illustrate how three possible polarization states in honeycomb materials allow the realization of more sophisticated geometries.

FIG. 10 is a schematic representation of the possible applications of the present invention in solar energy harvesting.

### DETAILED DESCRIPTION OF THE DRAWINGS

The above object, features and other advantages of the present invention will be best understood from the following detailed description in conjunction with the accompanying drawings, in which:

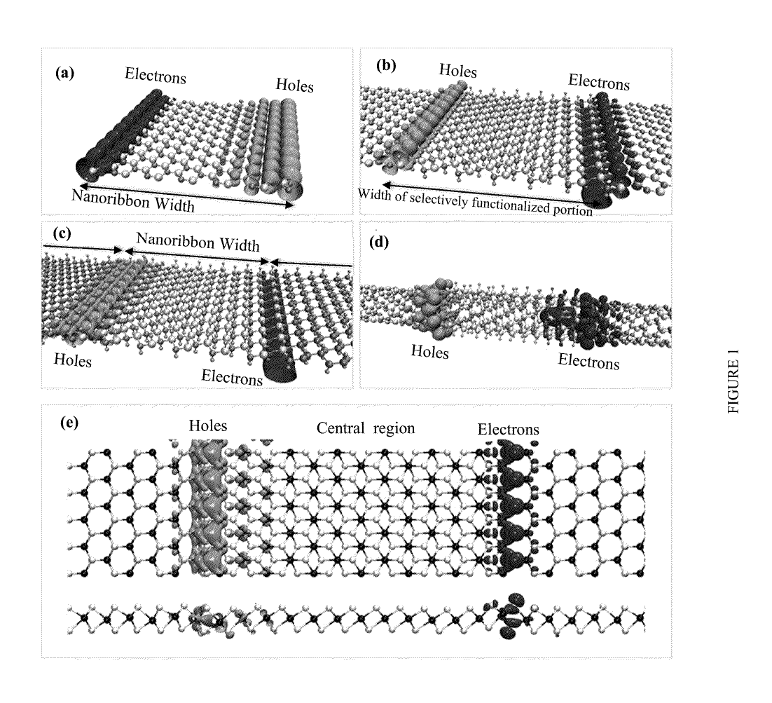

FIGS. 1(a), (b), (c), (d), and (e) illustrate possible realizations of a polar discontinuity in honeycomb lattices: (a) shows nanoribbons cut out of a two-dimensional heteronuclear honeycomb lattice (boron nitride in this case). The nanoribbon can infinitely extend along one of the two in-plane directions, while it has a finite width in the other direction. The interface has to be considered with vacuum, an insulator with vanishing polarization; (b) shows interfaces arising from selective functionalization (with hydrogen) of a parent honeycomb lattice (here boron nitride); (c) shows full functionalization of a heterostructure comprising graphene and boron nitride, the two most extensively studied two-dimensional honeycomb materials; (d) shows a nanotube obtained by rolling up a system like the one in (b) in such a way that it still manifests a polar discontinuity along its axis; (e) top and lateral view of a phase-engineered interface, in this case between the 1T phase (central region) and the 2H phase (at both sides) of a transition metal dichalcogenide (here ZrS₂). The real space distribution of free-carrier density is also plotted in dark (light) gray for electrons (holes);

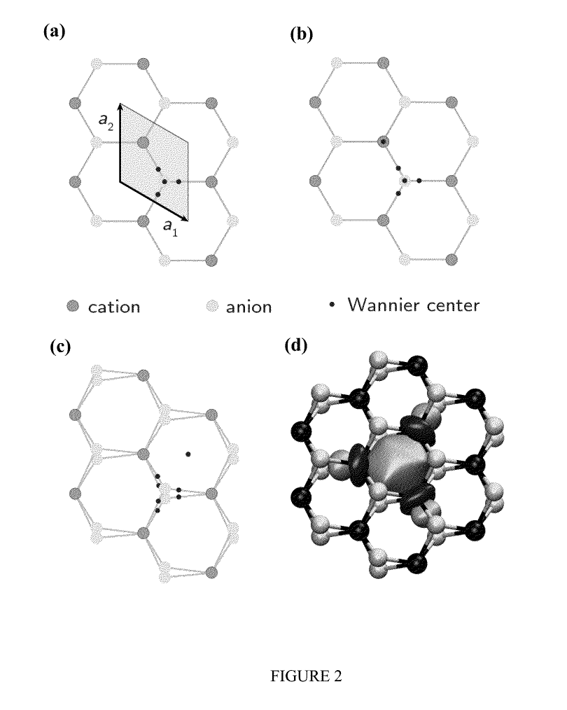

FIGS. 2(a), (b), (c), and (d) illustrate Wannier function centers in honeycomb lattices: (a) shows a crystal structure of a typical heteronuclear honeycomb lattice. Each unit cell, identified by two lattice vectors a₁ and a₂, includes two inequivalent lattice sites, occupied by a cation-like and an anion-like atom, respectively. In sp materials, the upper valence bands can be mapped to four doubly-degenerate Wannier functions centered around the anion. When the parent crystal is functionalized with hydrogen in chair configuration the effect is two-fold: (i) the effective ionic charge at each lattice site is increased by one unit and (ii) an additional Wannier function has to be included to accommodate the extra electrons; in (b) the in-plane projection of the corresponding center is on top of the cation while the other four Wannier functions remain localized around the anion as in (a); (c) shows Wannier function centers for group-VI transition metal dichalcogenides (e.g., MoS₂, WSe₂, etc.). Six doubly-degenerate Wannier functions are located around the chalcogens while another one is in the middle of the hexagonal cell; (d) shows an Isosurface plot of the latter Wannier function in the case of MoS₂ (Mo atoms in black and S atoms in gray);

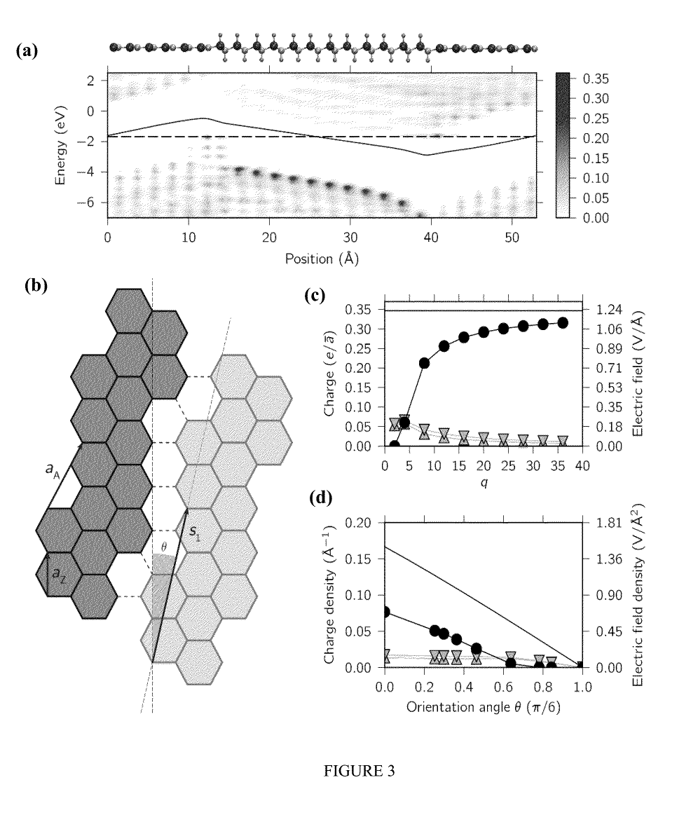

FIGS. 3(a), (b), (c), and (d) illustrate numerical results for BN—BNH₂ interfaces: (a) shows a grayscale plot representing the planar average of the local density of states as a function of energy and position along an axis orthogonal to the interfaces. These results have been obtained for a q=12 BN—BNH₂ superlattice with p=0 (purely zigzag interface) shown in lateral view on top. The horizontal dashed line marks the Fermi energy while the solid line denotes the macroscopic and planar average of the electrostatic potential energy; (b) is a schematic representation of an arbitrary interface orientation. The vectors a_{Z} and a_{A} lie along the zigzag and armchair directions, respectively. The lattice vector along the interface s₁ forms an angle θ with a purely zigzag direction and can be decomposed into zigzag and armchair steps as s₁=la_{Z}+pa_{A}, with l=2 and p=1 in this case; (c) shows an absolute value of the free charge (red circles) accumulated at each zigzag interface as a function of the integer q governing the periodicity of the superlattice. The horizontal solid line shows the expected asymptotic value given by equation (1). Up (down) triangles denote the residual average electric fields inside BN (BNH₂); (d) shows the same as (c) but as a function of the interface orientation angle θ for a q=7 superlattice. The solid line shows the expectation for the free charge density in the limit q→∞ according to equation (5). In (c) and (d) the left and right vertical axes can be easily mapped into each other by scaling according to the proper geometrical and physical factors;

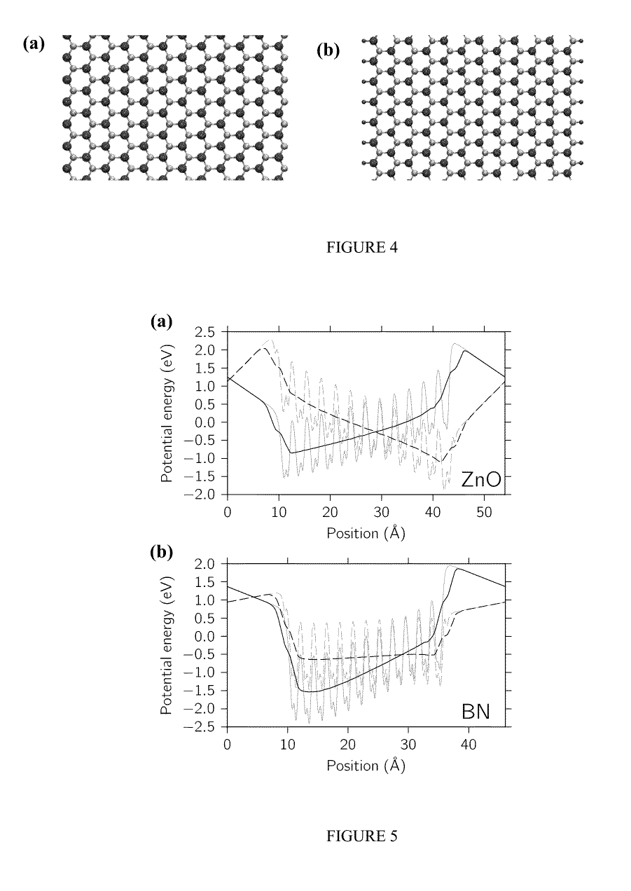

FIGS. 4(a) and (b) illustrate possible nanoribbon terminations, comparing a nanoribbon with unpassivated dangling bonds at the edges (a) and a nanoribbon with edge bonds saturated with hydrogen atoms (b);

FIGS. 5(a) and (b) illustrate the macroscopic average (black lines) on top of the planar average (gray lines) of the electrostatic potential energy as a function of the in-plane coordinate orthogonal to the nanoribbon edges. Results are reported for a theoretically postulated zinc oxide 2D hexagonal crystal (ZnO, (a)) and boron nitride (BN, (b)). Solid and dashed lines refer to ribbons with unpassivated and hydrogen-terminated dangling bonds, respectively. An electric field is present in materials like ZnO, which have m≠0 in equation (2), irrespective of the edge termination;

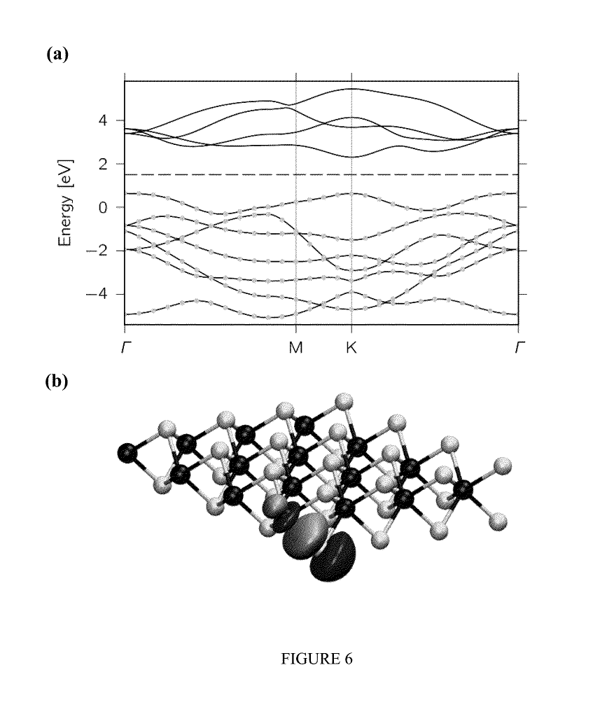

FIGS. 6(a) and (b) illustrate the band structure and Wannier functions of MoS₂. (a) shows MoS₂ band structure along a path in reciprocal space connecting the high-symmetry points Γ-M-K-Γ. Solid lines: original valence and conduction bands generated directly from a DFT calculation. The dashed line separates valence bands from conduction bands. Gray circles: Wannier-interpolated valence bands. The isolated top valence band is associated with the Wannier function shown in FIG. 2(d) above. The lower six valence bands can be mapped into maximally localized Wannier functions that are symmetrically equivalent to the one in (b) and show strong hybridization between sulphur p-orbitals and molybdenum d-orbitals;

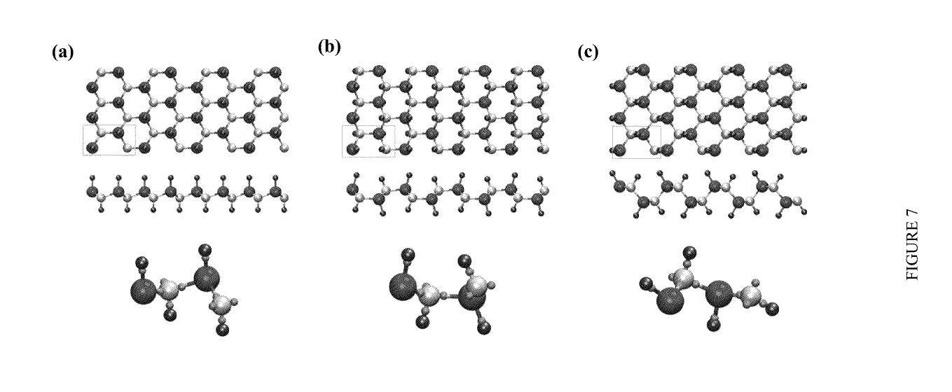

FIGS. 7(a), (b), and (c) illustrate possible conformers of functionalized honeycomb lattices. Top and lateral views of the three possible configurations of hydrogenated boron nitride that are compatible with a eight-atom unit cell: chair (a), boat (b), and stirrup (c). A gray rectangle highlights the eight-atom unit cell adopted in the calculations. The bottom panels show a magnified perspective view of each unit cell in which the Wannier function centers are also reported as small light gray spheres. In all panels boron atoms are depicted in dark gray, nitrogen atoms in light gray, and hydrogen atoms in black;

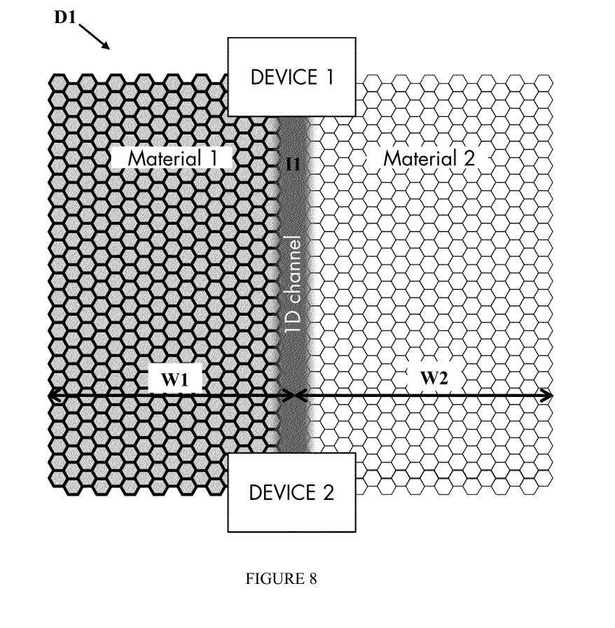

FIG. 8 illustrates a 1D channel of free carriers at the interface between two insulating materials with different polarization exploited to transfer a current signal from one device to another, exceeding the current limits of lithography;

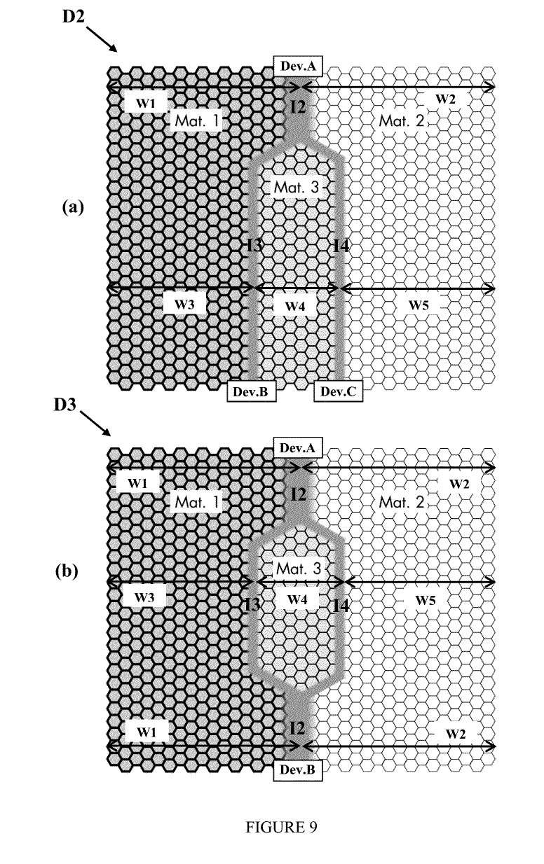

FIGS. 9(a) and (b) illustrate how three possible polarization states in honeycomb materials allow the realization of more sophisticated geometries like junctions where a single channel is split into two in order to connect multiple devices (a). (b) shows how a third material can be used to define a central region. If a magnetic field pierces this region, the interference between the currents flowing in the two arms (to the left and to the right of material 3) can be used to detect and measure the magnetic field; and

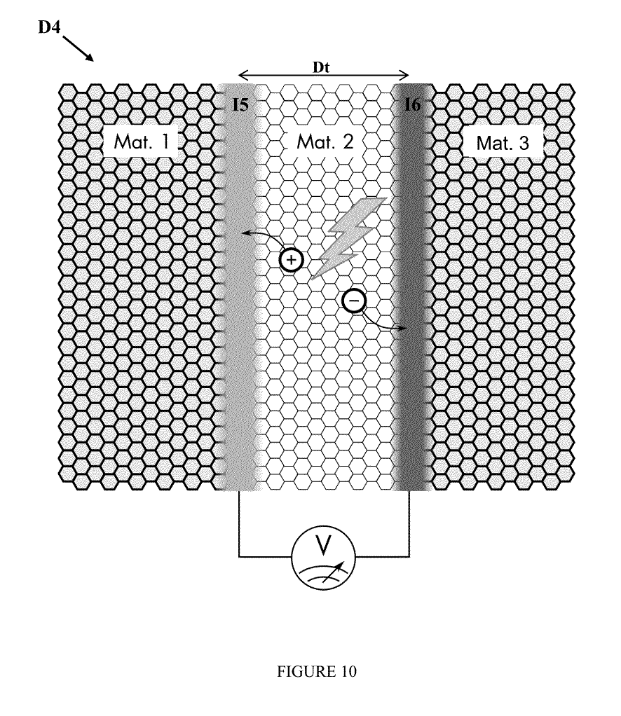

FIG. 10 is a schematic representation of the possible applications of the present invention in solar energy harvesting. When light is shined onto the device, it can be absorbed in the insulating bulk of the materials thus creating an electron hole pair. The built-in electric field associated with the polarization charges at the interfaces can then split the electron and the hole and drive them towards opposite interfaces. Here the electron and the hole can be collected through the 1D charge channels and create a bias that can be adopted to power an external device.

### DETAILED DESCRIPTION

### I.A: Nanoribbons: sp Materials

As a first realization of a polar discontinuity in honeycomb lattices we discuss a strip of material, usually called a nanoribbon (see FIG. 1a). In this case, the discontinuity has to be considered with vacuum and its polar character is manifested by the presence of polarization charges at the boundary of the crystal. According to the interface theorem¹⁶, the polarization charge density is related to the bulk formal polarization¹⁸, which, for non-centrosymmetric honeycomb crystals, is constrained by symmetry to have quantized values and to point along one of the equivalent armchair directions^{13,14,15} (i.e. parallel to the bonds, see FIG. 3):

$$P = \frac{e}{Σ} ( {a}_{1} + 2 {a}_{2} ) \frac{m}{3} + \frac{2 e}{Σ} R \qquad ( 2 )$$

In equation (2) a₁ and a₂ are the primitive lattice vectors (see FIG. 2), R is a generic Bravais lattice vector, Σ is the area of a unit cell, and mε{0, 1,2}. The value of m can be simply obtained once the ground state of the system is expressed in terms of a set of maximally-localized Wannier functions¹⁹. Then the electronic contribution to P can be expressed as a sum over point-like charges located at the Wannier centers <r>ⱼ and the total formal polarization reads⁴³

$$P = \frac{e}{Σ} ( {\sum }_{α = 1}^{N} {Z}_{α} {τ}_{α} - 2 {\sum }_{j = 1}^{{N}_{el} / 2} {〈 r 〉}_{j} ) . \qquad ( 3 )$$

Here Z_{α} and τ_{α} are the charge and positions of the N ions in the unit cell and Nₑₗ is the number of electrons. Let us first consider hetero-atomic honeycomb lattices in which the electronic properties are determined by s and p orbitals. These include for instance BN, SiC, ZnO, etc. In FIG. 2a we show the Wannier function centers of such systems and by using equation (2) it is easy to show that the bulk formal polarization is non-zero for many of them (see Table I). A finite polarization charge thus appears at the edges of a nanoribbon made out of one of these honeycomb crystals, provided that the formal polarization vector is not parallel to the edge. In our numerical simulations, the presence of this polarization charge is manifested by the existence of a finite electric field inside the nanoribbon. We have verified that, in agreement with the interface theorem¹⁶, the polarization charge is maximal for (perfect) zigzag edges (i.e. along a direction orthogonal to the bonds, see FIG. 3) while it vanishes for nanoribbons with armchair edges. It is important to mention that, depending on the edge termination, additional charges might appear at the boundary. Nonetheless, since the polarization charge is typically a non-integer fraction of an electron per unit length (with the exception of III-V ribbons like BN or AlN for which m=0), any specific termination does not affect the presence of a finite electric field since it changes the polarization by an integer number of electrons per unit length, although it might reverse the sign of the polarization charge (see below section Supplementary Material 1).

For zigzag edges, by increasing the width of the nanoribbon, the electric field induces a metal-insulator transition in the system. As shown in FIG. 1a, free carriers localize close to edges of the nanoribbon and have different character (electrons or holes) on opposite sides. The density of free carriers at each edge increases with the width of the nanoribbon and, asymptotically, perfectly screens the polarization charge in agreement with equation (1). It is thus possible to tune such nanoribbons from a regime of small widths (few nanometers, for example between 1 nm and 10 nm) in which there is a sizable electric field and negligible density of free carriers to an opposite regime for large widths (tens of nanometers or more, for example >10 nm and <100 nm, and preferably >10 nm and <50 nm) of vanishing electric fields but high metallicity.

FIG. 1 illustrates possible realizations of a polar discontinuity in honeycomb lattices. FIG. 1(a) shows nanoribbons cut out of a two-dimensional heteronuclear honeycomb lattice (boron nitride in this case). The nanoribbon can infinitely extend along one of the two in-plane directions, while it has a finite width in the other direction. The interface has to be considered with vacuum, an insulator with vanishing polarization. FIG. 1(b) shows interfaces arising from selective functionalization (with hydrogen) of a parent honeycomb lattice (here boron nitride). FIG. 1(c) shows full functionalization of a heterostructure comprising graphene and boron nitride, the two most extensively studied two-dimensional honeycomb materials. FIG. 1(d) shows a nanotube obtained by rolling up a system like the one in (b) in such a way that it still manifests a polar discontinuity along its axis. FIG. 1(e) top and lateral view of a phase-engineered interface, in this case between the 1T phase (central region) and the 2H phase (at both sides) of a transition metal dichalcogenide (here ZrS₂). The real space distribution of free-carrier density is also plotted in dark (light) gray for electrons (holes).

At this point it is important to mention that metallicity of such zigzag nanoribbons has been theoretically investigated in recent years^{20,21,22,23}. In particular it has been pointed out that such 1D metallic channels can undergo magnetic transitions and eventually become half-metallic. However, no connection with the intrinsic polarization of these materials has been drawn. This means in particular that the existence of a finite electric field in small-width nanoribbons has not been discussed before. As we shall discuss later, this is actually one of the key features that make these systems very promising for solar-energy applications.

From an experimental point of view, the main challenge would be to have an atomic-scale control over the edge structure. Indeed, although the effects described here would be present not only for zigzag orientations but also for different edge orientations (see below), edge defects could introduce additional charges at the edges that might screen the polarization charge. On the other hand, recent progress^{24,25} in the atomistic control over the edge structure of graphene nanoribbons is extremely promising and could be extended to other honeycomb crystals.

### I.B: Nanoribbons: Transition-Metal Dichalcogenides

In addition to sp materials, there exist other honeycomb lattices that support a finite bulk polarization: group-VI transition metal dichalcogenides MX₂. In such systems one sublattice is occupied by a transition metal M while the other hosts two chalcogens X displaced in the vertical direction on opposite sides with respect to the plane of M atoms. Although these materials have been extensively studied in last few years, their bulk formal polarization has been not discussed so far. In FIG. 2c we show the Wannier function centers for the top seven valence bands when the group-VI transition metal M is either Mo or W. Six centers lie close to the X atoms (with X═S, Se, or Te), which then play the role of “anions”, while the last one is located at the center of the hexagonal cell and is associated with the Wannier function displayed in FIG. 2d. As a consequence group-VI transition metal dichalcogenides like MoS₂ have a non-trivial (i.e. m≠0) formal polarization and thus give rise to a polar discontinuity when cut into nanoribbons, in analogy with what happens for sp materials. In addition, we mention that a polar discontinuity occurs also across inversion domain boundaries, i.e. at interfaces that bridge together two different regions of a polycrystalline sample in which their local structure is related by inversion symmetry. Indeed, when such inversion domain boundaries lie along zigzag directions, they separate crystallites with opposite polarizations and thus support a polar discontinuity. Thus, group-VI transition metal dichalcogenides offer a broad choice in materials, chemistry, and electronic structure, and represent one of the most promising experimental avenues to pursue. Indeed, polarization effects might be at the origin of metallic states already observed at inversion domain boundaries in MoSe₂ and at the edge of MoS₂ nanoclusters.

### II: Phase-Engineered Interfaces

Contrary to group-VI transition metal dichalcogenides, other 2D transition metal dichalcogenides have a different crystal structure. These include group-IV transition metal dichalcogenides where the metal M is titanium (Ti), zirconium (Zr), or hafnium (Hf). In this case, the chalcogen atoms above and below the plane of M atoms form two distinct hexagonal sublattices displaced along an armchair direction. This gives the M atom an octahedral coordination and the phase is usually denoted 1T, as opposed to the 2H phase typical of group-VI transition metal dichalcogenides (described above) where the metal M shows a trigonal prismatic coordination. Owing to the increased symmetry in the 1T phase, it turns out that the bulk formal polarization of group-IV transition metal dichalcogenides vanishes. This means that interfaces between group-VI and group-IV transition metal dichalcogenides support a finite polar discontinuity and it is thus another platform for the realization of 1D wires of free carriers. Such interfaces could be realized by changing during growth the transition metal atom (e.g., leading to TiS₂—MoS₂ interfaces) or both the transition metal and the chalcogen (giving rise for instance to interfaces between HfS₂ and MoSe₂), generalizing the recent developments in group-VI-group-VI interfaces.

Moreover, we stress that, although the stable phase of group-IV transition metals is the 1T phase, these 2D materials could be prepared into the (metastable) 2H phase. In order to determine the formal polarization of such metastable structures, we have computed the Wannier functions for the relevant valence bands. Similarly to the case of the 2H phase of group-VI transition metal dichalcogenides (see FIG. 2c), we have six Wannier functions that are centered close to the chalcogen atoms, while the Wannier function located in the middle of the hexagonal cell is not occupied in this case owing to the different number of valence electrons in group-IV transition metal dichalcogenides. This means that the formal polarization of the 2H phase is non-zero even when M=Ti, Hf, or Zr (the only exception being TiSe₂ that is metallic both in the 1T and the 2H phase) but it is still different from the case of group-VI transition metal dichalcogenides.

This opens at least four possible ways towards the realization of polar discontinuities in honeycomb lattices: (i) nanoribbons of the metastable 2H phase in analogy to the case of group-VI transition metal dichalcogenides; (ii) interfaces between group-VI transition metal dichalcogenides in the 2H phase and group-IV in the 1T phase; (iii) interfaces between group-VI and group-IV transition metal dichalcogenides both in the 2H phase; and (iv) interfaces between different phases (1T-2H) of group-IV transition metal dichalcogenides (see FIG. 1e).

Finally we mention that, complementarily to what has been discussed in the previous paragraph, one could induce group-VI transition metal dichalcogenides into the metastable 1T phase. Although many theoretical calculations suggest that these phases are metallic, in some materials a small gap could be induced by spin-orbit interactions even in this case. The polarization of this gapped 1T phase would then be zero, thus paving the way for additional interfaces supporting polar discontinuities like for instance the 2H and 1T phase of a common parent group-VI transition metal dichalcogenide.

The crucial step in the last proposals is the preparation of the metastable phases. This has already been done (e.g., by electron beams) in the case of MoS₂ (where, however, the metastable phase is metallic and thus not relevant for the creation of a polar discontinuity), and could be extended to the materials mentioned here. In addition, other methods could be exploited: (i) mechanical techniques where the switch to the metastable phase is induced by local mechanical pressure along the vertical direction exerted, for instance using a STM tip; (ii) electrostatic techniques, where instead the switch is triggered by gating or by an external electric field; and (iii) thermal techniques, where a local change in temperature (due for instance to a focused laser beam) gives rise to a phase transition (see also Supplementary Material 2).

### III.A: Selective Functionalization

As an additional route towards the realization of a polar discontinuity in honeycomb lattices we investigate the effects of covalent functionalization (functionalization or functionalizing refers to a modification or alteration of a lattice by addition of (functionalization) substances), i.e. the chemical bonding of an atom, such as hydrogen or fluorine, or a molecule, such as a carbene, a nitrene, or a phenyl group.

In the following we shall consider different possible configurations:

1) full functionalizations, where every atom of the original (“parent”) honeycomb lattice acquire by means of a physical or chemical treatment an additional covalent (i.e. chemical) bond with an added atom or molecule.
2) partial functionalizations, a process analogue to full functionalizations, where only a subset of atoms belonging to the parent honeycomb lattice acquire a covalent bond with an added atom or molecule. This subset of atoms can be ordered or disordered—in the former case it is said to form a sublattice.
3) selective functionalizations, defined as a full or partial functionalization of only a selected region of space within the parent honeycomb lattice, or a repeating pattern of such regions. Let us first assume full coverage (i.e. each atom of the honeycomb lattice is functionalized) and consider for simplicity a chair conformation, corresponding to functional atoms being bonded in alternating positions above and below the plane of the parent honeycomb lattice. This conformation leaves unaffected the 2D space-group of the crystal so that the polarization is still quantized according to equation (2). Other conformations with reduced symmetry might be more stable depending on the parent material considered, but we stress that our conclusions would be qualitatively unaltered (see Supplementary Material 1). In FIG. 2b we show the Wannier function centers for a typical functionalized honeycomb lattice. We report results only for hydrogen since the case of fluorine is completely analogous. In fact, the six additional positive ionic charges of F with respect to H are completely balanced by three additional Wannier functions that are symmetrically arranged around the F atom. By close inspection it is easy to verify that functionalization changes the value of m in equation (2) by one unit with respect to the parent material. As a consequence, we first notice that functionalization enhances the stability of polar discontinuities with respect to edge termination in nanoribbons of III-V materials by changing m from 0 to 1 (see Table I). In addition, selective functionalization of a region of a honeycomb lattice creates an interface between pristine and functionalized regions, thus introducing a polar discontinuity in the system. This situation is depicted in FIG. 1b, where we consider perfect zigzag interfaces (giving rise to a maximal polar discontinuity) between alternating strips of pure and hydrogenated BN. Below we shall discuss at length this case and here we simply mention that the electric field associated with the polar discontinuity gives rise, as expected, to a metal-insulator transition with the appearance of free carriers localized at the interfaces (see FIG. 1b).

TABLE I
Possible material classes and methods that can be applied to obtain a
polar discontinuity, and thus create free charge channels and an electric
field in the bulk of a 2D material. Each materials class is labeled using a
representative materials: BN for III-V; SiC for IV-IV; ZnO for II-VI,
MoS₂ for group-VI transition metal dichalcogenides); ZrS₂ for group-IV
transition metal dichalcogenides; BNH₂ for functionalized III-V materials,
SiCH₂ for functionalized IV-IV materials, and ZnOH₂ for functionalized
II-VI materials - of course the choices of materials within each materials
class are much broader. For clarity, we relegate IV-IV and II-VI
monolayers and their functionalizations in the lower part of the table,
given the lack, at present, of experimental routes to creating these.

| Material | | | Phase- | Selective |
|---|---|---|---|---|
| class | m | Nanoribbon | engineering | functionalization |
| BN | 0 | [symbol] ^{a} | [symbol] | ✓ |
| BNH₂ | 1 | ✓ | [symbol] | |
| MoS₂-2H | 1 | ✓ | ✓ | ✓^{b} |
| MoS₂-1T | 0 | [symbol] | | ✓^{b} |
| ZrS₂-1T | 0 | [symbol] | | ✓^{b} |
| ZrS₂-2H | 2 | ✓ | | ✓^{b} |
| SiC | 2 | ✓ | ✓ | ✓ |
| SiCH₂ | 0 | [symbol] ^{a} | [symbol] ^{a} | |
| ZnO | 1 | ✓ | ✓ | ✓ |
| ZnOH₂ | 2 | ✓ | ✓ | |

^{a}In this case a polar discontinuity is still possible but some nanoribbon edge terminations can remove it.
^{b}In principle selective functionalization works for transition metal dichalcogenides, even though it would be very difficult to realize in practice.

At variance with the direct growth of interfaces between different honeycomb lattices¹⁵, this method has the crucial advantage that the two crystals (pristine and functionalized) are naturally aligned with respect to each other. The experimental challenge is thus shifted to the selective functionalization of the parent crystal. In order to achieve this result, it is likely that techniques adopted for the functionalization of graphene^{26,27} could be easily adapted to heteroatomic honeycomb crystals. Full coverage, double-sided hydrogenation of graphene with chair configuration (known as graphane) has been realized in suspended samples by exposure to low-temperature hydrogen plasmas²⁸. As far as fluorographene is concerned, a 1:1 carbon to fluorine ratio is achievable by functionalization with atomic fluorine formed by decomposition of xenon difluoride (XeF₂)^{29,30}. By combining this technique with scanning probe lithography a pristine graphene nanoribbon has been isolated within a matrix of partially fluorinated graphene³¹. In addition, encouraging results have been already reported on the partial fluorination of BN nanotubes³² and nanosheets³³.

FIG. 2 illustrates Wannier function centers in honeycomb lattices. FIG. 2(a) shows a crystal structure of a typical heteronuclear honeycomb lattice. Each unit cell, identified by two lattice vectors a₁ and a₂, includes two inequivalent lattice sites, occupied by a cation-like and an anion-like atom, respectively. In sp materials, the upper valence bands can be mapped to four doubly-degenerate Wannier functions centered around the anion. When the parent crystal is functionalized with hydrogen in chair configuration the effect is two-fold: (i) the effective ionic charge at each lattice site is increased by one unit and (ii) an additional Wannier function has to be included to accommodate the extra electrons. In FIG. 2(b) the in-plane projection of the corresponding center is on top of the cation while the other four Wannier functions remain localized around the anion as in FIG. 2(a). FIG. 2(c) shows Wannier function centers for group-VI transition metal dichalcogenides (e.g., MoS₂, WSe₂, etc.). Six doubly-degenerate Wannier functions are located around the chalcogens while another one is in the middle of the hexagonal cell. FIG. 2(d) shows an isosurface plot of the latter Wannier function in the case of MoS₂ (Mo atoms in black and S atoms in gray).

### III.B: Functionalized Graphene/Boron Nitride Interfaces

In view of the well-established experimental technology in graphene and boron nitride (as compared to other honeycomb lattices) and the recent achievements¹⁷ in graphene/boron nitride lateral interfaces, it would be interesting to exploit these materials to engineer a polar discontinuity. Pristine graphene is not an insulator and it does not support a bulk polarization. On the other hand, its functionalized forms (graphane and fluoro-graphene) are insulators and their formal polarization is constrained by symmetry to be vanishing^{13,14}. In addition, we have seen above that functionalized BN acquires a non-trivial bulk polarization. Thus, we may consider complete or full functionalization of planar graphene/boron nitride heterostructures. In FIG. 1c we show this additional set-up together with the density of free carriers that appears at the interfaces as a consequence of the electrostatic instability associated with the polarization-induced electric field.

As the experimental know-how evolves to achieve atomistic control of graphene/BN interfaces along the zigzag direction¹⁷, this technique would greatly benefit from the requirement of full functionalization—i.e. each atom in the honeycomb lattice is functionalized, as opposed to partial functionalization (where only an ordered subset of atoms is functionalized) and selective functionalization (where full or partial functionalization takes place in a selected area), as suggested in the previous section—.

### III.C: Functionalized Nanotubes

Up until now the description of the present invention has been mainly devoted to 2D systems. We would now like to describe and illustrate what happens when the honeycomb lattices described in all the previous sections are rolled up into tubes. Such nanotubes acquire a finite polarization along the axis depending on the polarization of the parent 2D crystal and on the chirality of the nanotube³⁴. Focusing on zigzag nanotubes, we thus notice that by selective functionalization, as illustrated in FIG. 1d, one can introduce a polar discontinuity along the tube. Similarly to what happens in 2D, a finite polarization charge builds up at the interfaces and creates an electric field in the bulk of the system. By increasing the distance between consecutive interfaces, a charge transfer occurs between them, thus creating electron- and hole-rich quantum dots. The charge density localized in these quantum dots is shown in FIG. 1d in the case of a BN nanotube with selective hydrogen functionalization.

The reduced dimensionality suggests that the effects of Coulomb interactions might be relevant for the electronic structure properties of such quantum dots. The interaction-driven phenomena that might arise would then be interesting both from a fundamental and practical point of view.

In addition, even in the regime of small system sizes (˜1 nm, when no charge is transferred in the quantum dots), the magnitude of the electric field in each segment of the nanotube could be easily tuned by varying the diameter of the nanotube and the distance between the interfaces. As we shall discuss in the following, this has significant consequences in solar-energy applications where the electric field is used not only to spatially separate electrons and holes but also to modify the absorption spectrum of the system.

### Results

In order to support the general physical arguments discussed above, we now report on our numerical simulations of polar discontinuities in honeycomb lattices. For definiteness we will focus on selective hydrogen functionalization of BN, even though qualitatively similar results can be obtained using different parent materials and functional atoms or the alternative approaches introduced above to engineer polar discontinuities.

In order to simulate with periodic boundary conditions interfaces between pristine and functionalized BN, we consider superlattices obtained by alternating BN and BNH₂ ribbons. As a consequence, two opposite interfaces are always present within a single supercell that can be properly constructed by defining the corresponding lattice vectors. The one along the interface can be identified by specifying the number of zigzag and armchair sections present, as shown in FIG. 3b: s₁=la_{Z}+pa_{A}, where l and p are positive coprime integers and a_{Z}=a₂ (a_{A}=a₁+2a₂) is the translation vector along the zigzag (armchair) direction. It is important to mention that the lattice vector s₁ alone is not sufficient to define the boundary since we need to specify how lattice sites should be assigned to each ribbon. For simplicity we consider only minimal boundaries³⁵, i.e. we consider interfaces that, given the integers l and p, minimize the number of boundary atoms and bonds. Different choices would affect the results, through the appearance of additional bound charges at the interface. The second lattice vector depends on the number of repetitions q that define the width of each ribbon: s₂=2qa₁, where the direction along a₁ has been chosen in order to maximize the orthogonality with s₁.

We first focus on the case of a perfect zigzag interface (p=0). According to the interface theorem, we have a finite polarization charge density with opposite signs at the two interfaces. This creates electric fields both inside BN and BNH₂, as can be clearly seen in FIG. 3a from the finite slopes of the macroscopic and planar average of the electrostatic potential (solid line). In FIG. 3 we also show the average local density of states (LDOS) as a function of energy and position orthogonal to the interface. We notice that, as a consequence of the electric fields, the energy bands are linearly shifted in space. For sufficiently large widths of the ribbons (as in FIG. 3a), this leads to an energy overlap between the conduction and valence bands at the two interfaces that gives rise to a charge redistribution with the creation of electron and hole pockets^{12,15}. The Fermi energy (dashed line) intersects both the top valence bands and the bottom conduction bands so that the system is metallic, as expected. FIG. 1b shows the excess charge density obtained by properly integrating the LDOS in order to take into account the partial depletion of the valence bands (for holes) and filling of the conduction bands (for electrons). Both figures make thus clear that the excess electrons and holes are separated in space and reside on opposite interfaces, partially screening the polarization charges.

In FIG. 3c we report the density of free carriers for different widths of the ribbons (circles). As the periodicity of the superlattice increases, the charge of free electrons and holes also increases as a result of a larger overlap between conduction and valence bands. Since the free charge has an opposite sign with respect to the polarization charge, the overall charge density at each interface decreases together with the electric field in both materials (triangles in FIG. 3c). Asymptotically, the free charge completely balances the polarization charge according to equation (1) and the electric fields vanish, thus preventing a polar catastrophe¹¹. Indeed, in FIG. 3c the density of free carriers approaches asymptotically the horizontal solid line that marks the polarization charge obtained from the bulk formal polarizations of BN and BNH₂. If the two materials were perfectly lattice-matched we would have from the discussion on Wannier functions above [equations (1) and (2)] that |λ_{P}|=e/(3a). Owing to the piezoelectric properties of these materials, this value is slightly larger than e/(3ā) as a result of the finite strain necessary to reach an equilibrium lattice constant ā along the interface.

FIG. 3 illustrates numerical results for BN—BNH₂ interfaces. FIG. 3(a) shows a grayscale plot representing the planar average of the local density of states as a function of energy and position along an axis orthogonal to the interfaces. These results have been obtained for a q=12 BN—BNH₂ superlattice with p=0 (purely zigzag interface) shown in lateral view on top. The horizontal dashed line marks the Fermi energy while the solid line denotes the macroscopic and planar average of the electrostatic potential energy. FIG. 3(b) is a schematic representation of an arbitrary interface orientation. The vectors a_{Z} and a_{A} lie along the zigzag and armchair directions, respectively. The lattice vector along the interface s₁ forms an angle θ with a purely zigzag direction and can be decomposed into zigzag and armchair steps as s₁=la_{Z}+pa_{A}, with l=2 and p=1 in this case. FIG. 3(c) shows an absolute value of the free charge (red circles) accumulated at each zigzag interface as a function of the integer q governing the periodicity of the superlattice. The horizontal solid line shows the expected asymptotic value given by equation (1). Up (down) triangles denote the residual average electric fields inside BN (BNH₂). FIG. 3(d) shows the same as FIG. 3(c) but as a function of the interface orientation angle θ for a q=7 superlattice. The solid line shows the expectation for the free charge density in the limit q→∞ according to equation (5). In FIGS. 3(c) and (d) the left and right vertical axes can be easily mapped into each other by scaling according to the proper geometrical and physical factors.

Let us now consider an arbitrary interface orientation that can be identified by the angle θ between the lattice vector along the interface, s₁, and the pure zigzag direction, a_{Z}, so that

$$cos θ = \frac{{s}_{1} \cdot {a}_{z}}{\vert {s}_{1} \vert \vert {a}_{z} \vert} = \frac{3 p + 2 𝓁}{2 \sqrt{3 {p}^{2} + 3 p 𝓁 + {𝓁}^{2}}} \qquad ( 4 )$$

According to equations (1) and (2) the polarization charge density gradually decreases down to zero as θ goes from zero (pure zigzag, p=0) to π/6 (pure armchair, l=0). In particular, neglecting for simplicity piezoelectric effects, we find

$$\vert {λ}_{p} \vert = \frac{2 e}{3 \overline{a}} sin ( \frac{π}{6} - θ ) . \qquad ( 5 )$$

Thus, we expect that the appearance of finite electric fields and the presence of a metal-insulator transition are not restricted to the case θ=0, although their effects are depressed as we approach θ=π/6. FIG. 3d shows the free charge density and the electric fields in BN and BNH₂ for several values of θ corresponding to different combinations of l and p. All simulations have been performed keeping fixed the periodicity of the superlattice (q=7). We notice that despite the small width of the system, the free charge density survives over a wide range of angles thus suggesting a reasonable robustness with respect to the interface orientation. In addition, owing to the presence of residual electric fields, we expect that by incrementing the periodicity of the superlattice the free charge density could be further increased and asymptotically reach the solid line representing the polarization charge in equation (5), as it happens in the θ=0 case shown in FIG. 3c.

In conclusion we have presented different approaches to obtain polar discontinuities in honeycomb lattices, supporting the predictions with first-principles simulations. First, cutting a 2D sheet into a strip (nanoribbon) introduces a polar discontinuity with vacuum if the parent material supports a finite formal polarization. This happens for many hetero-atomic honeycomb crystals like, e.g., silicon carbide and for transition metal dichalcogenides like molybdenum disulfide. Second, a change in the crystal phase and/or in the metal atom (from group-IV to group-VI or vice versa) in 2D transition metal dichalcogenides is associated with a change in the bulk formal polarization of the material. Thus, by engineering the phase and/or the chemical composition of transition metal dichalcogenides it is possible to induce a polar discontinuity in the system. Finally, covalent atomic functionalizations, for instance with hydrogen or fluorine, change the bulk polarization of a honeycomb lattice. Thus, covalent functionalization can be used to engineer polar discontinuities both in 2D sheets or 1D nanotubes simply by introducing interfaces between functionalized and pristine sections. In addition, since covalent functionalizations open a gap in graphene, these might be exploited to engineer polar discontinuities in graphene/boron nitride interfaces without the need for selective functionalization.

The first consequence of a polar discontinuity is the appearance of polarization charges at the interfaces. For narrow systems such polarization charges give rise to finite electric fields in the bulk. As the distance between the interfaces (size of the system) increases, the electric field triggers a metal-insulator transition, with the appearance of free carriers at the boundaries. Such polar discontinuities in honeycomb lattices will provide a promising framework for innovative applications.

First, 1D channels of free carriers along the interfaces can be exploited for circuitry in new-generation ultra-thin (i.e. few-atom thick) and flexible electronics. Indeed, current signals between different units of a device could be transmitted along such 1D channels, surrounded by insulating bulk materials, exceeding the limits of lithography in current electronic devices. Moreover, the reduced dimensionality of the channels gives rise to magnetic instabilities that could be useful in spintronics applications.

Last, we envision a fruitful usage in solar energy technology for the realization of compact ultra-thin solar cells. Indeed, the bulk of these systems is insulating and represents the active region where photons can be absorbed creating an electron-hole pair. For narrow systems (up to approximately few tens of nanometers), the polarization charge at the interfaces/edges is not compensated and thus creates an electric field. The advantage of this electric field is two-fold. (i) On one side, once the electron-hole pair is created, the electric field separates them and guides them towards opposite interfaces, where the 1D charge channels can be exploited to collect them and produce a finite bias. (ii) On the other hand, the electric field shifts in space the conduction and valence band extrema. This creates a variable effective gap depending on the spatial separation between the electron and the hole, i.e. on the extension of the exciton, with an ensuing increase of the cell efficiency. In addition, several systems with different widths and materials composition could be integrated into a single device in order to optimize the range of photon frequencies that can be absorbed.

### Methods

All first-principles calculations reported here are carried out within density-functional theory by using the PWscf code of the Quantum-ESPRESSO distribution³⁶ with the Perdew-Burke-Ernzerhoff exchange-correlation functional³⁷. An ultrasoft pseudopotential description³⁸ of the ion-electron interaction is adopted. Energy cutoffs are set to 60 Ry and 300 Ry respectively for the electronic wavefunctions and the charge density in the case of BN/BNH₂ superlattices. For zigzag interfaces a 1×6×1 shifted Monkhorst-Pack grid³⁹ is used to sample the Brillouin zone together with a 0.01 Ry Marzari-Vanderbilt smearing⁴⁰. In order to simulate a 2D system irrespective of the three-dimensional periodicity requirements of plane-wave basis sets, a vacuum layer of 20 Å is added between periodic replicas in the vertical direction. Relaxed structures are obtained within the Broyden-Fletcher-Goldfarb-Shanno method by requiring that the forces acting on atoms are below 0.026 eV/Å and the residual stress on the cell is less than 0.5 kbar. Some simulations have been performed without relaxation in order to simplify the calculations without qualitatively affecting our results. Maximally-localized Wannier functions have been computed using Wannier90⁴¹.

### REFERENCES 1

¹ J. Mannhart and D. G. Schlom, Science 327, 1607 (2010)
² P. Zubko, S. Gariglio, M. Gabay, P. Ghosez, and J.-M. Triscone, Annu. Rev. Cond. Mat. Phys. 2, 141 (2011)
³ H. Y. Hwang, Y. Iwasa, M. Kawasaki, B. Keimer, N. Nagaosa, and Y. Tokura, Nat. Mater. 11, 103 (2012)
⁴ A. Ohtomo and H. Y. Hwang, Nature 427, 423 (2004)
⁵ N. Reyren, S. Thiel, A. D. Caviglia, L. F. Kourkoutis, G. Hammerl, C. Richter, C. W. Schneider, T. Kopp, A.-S. R_etschi, D. Jaccard, M. Gabay, D. A. Muller, J.-M. Triscone, and J. Mannhart, Science 317, 1196 (2007)
⁶ A. Brinkman, M. Huijben, M. van Zalk, J. Huijben, U. Zeitler, J. C. Maan, W. G. van der Wiel, G. Rijnders, D. H. A. Blank, and H. Hilgenkamp, Nat. Mater. 6, 493 (2007)
⁷ L. Li, C. Richter, J. Mannhart, and R. C. Ashoori, Nat. Phys. 7, 762 (2011)
⁸ J. A. Bert, B. Kalisky, C. Bell, M. Kim, Y. Hikita, H. Y. Hwang, and K. A. Moler, Nat. Phys. 7, 767 (2011)
⁹ S. Thiel, G. Hammerl, A. Schmehl, C. W. Schneider, and J. Mannhart, Science 313, 1942 (2006)
¹⁰ R. Pentcheva and W. E. Pickett, J. Phys. Condens. Matter 22, 043001 (2010)
¹¹ N. Bristowe, P. Ghosez, P. Littlewood, and E. Artacho, arXiv:1310.8427 (2013)
¹² A. Janotti, L. Bjaalie, L. Gordon, and C. G. Van de Walle, Phys. Rev. B 86, 241108 (2012)
¹³ C. Fang, M. J. Gilbert, and B. A. Bernevig, Phys. Rev. B 86, 115112 (2012)
¹⁴ P. Jadaun, D. Xiao, Q. Niu, and S. K. Banerjee, Phys. Rev. B 88, 085110 (2013)
¹⁵ N. C. Bristowe, M. Stengel, P. B. Littlewood, E. Artacho, and J. M. Pruneda, Phys. Rev. B 88, 161411 (2013)
¹⁶ D. Vanderbilt and R. D. King-Smith, Phys. Rev. B 48, 4442 (1993)
¹⁷ P. Sutter, R. Cortes, J. Lahiri, and E. Sutter, Nano Letters 12, 4869 (2012); M. P. Levendorf, C.-J. Kim, L. Brown, P. Y. Huang, R. W. Havener, D. A. Muller, and J. Park, Nature 488, 627 (2012); Z. Liu, L. Ma, G. Shi, W. Zhou, Y. Gong, S. Lei, X. Yang, J. Zhang, J. Yu, K. P. Hackenberg, A. Babakhani, J.-C. Idrobo, R. Vajtai, J. Lou, and P. M. Ajayan, Nat Nanotechnol. 8, 119 (2013); L. Liu, J. Park, D. A. Siegel, K. F. McCarty, K. W. Clark, W. Deng, L. Basile, J. C. Idrobo, A.-P. Li, and G. Gu, Science 343, 163 (2014)
¹⁸ R. Resta, Rev. Mod. Phys. 66, 899 (1994)
¹⁹ N. Marzari, A. A. Mostofi, J. R. Yates, I. Souza, and D. Vanderbilt, Rev. Mod. Phys. 84, 1419 (2012)
²⁰ Y. Li, Z. Zhou, S. Zhang, and Z. Chen, Journal of the American Chemical Society 130, 16739 (2008)
²¹ V. Barone and J. E. Peralta, Nano Letters 8, 2210 (2008)
²² A. R. Botello-Mendez, F. Lopez-Urias, M. Terrones, and H. Terrones, Nano Letters 8, 1562 (2008), pMID: 18177062
²³ P. Lou, Phys. Chem. Chem. Phys. 13, 17194 (2011)
²⁴ K. Kim, S. Coh, C. Kisielowski, M. F. Crommie, S. G. Louie, M. L. Cohen, and A. Zettl, Nat. Commun. 4, 2723 (2013)
²⁵ X. Zhang, 0. V. Yazyev, J. Feng, L. Xie, C. Tao, Y.-C. Chen, L. Jiao, Z. Pedramrazi, A. Zettl, S. G. Louie, H. Dai, and M. F. Crommie, ACS Nano 7, 198 (2013)
²⁶ F. Karlický, K. Kumara Ramanatha Datta, M. Otyepka, and R. Zbo\check{r}il, ACS Nano 7, 6434 (2013)
²⁷ J. E. Johns and M. C. Hersam, Acc. Chem. Res. 46, 77 (2013)
²⁸ D. C. Elias, R. R. Nair, T. M. G. Mohiuddin, S. V. Morozov, P. Blake, M. P. Halsall, A. C. Ferrari, D. W. Boukhvalov, M. I. Katsnelson, A. K. Geim, and K. S. Novoselov, Science 323, 610 (2009)
²⁹ R. R. Nair, W. Ren, R. Jalil, I. Riaz, V. G. Kravets, L. Britnell, P. Blake, F. Schedin, A. S. Mayorov, S. Yuan, M. I. Katsnelson, H.-M. Cheng, W. Strupinski, L. G. Bulusheva, A. V. Okotrub, I. V. Grigorieva, A. N. Grigorenko, K. S. Novoselov, and A. K. Geim, Small 6, 2877 (2010)
³⁹ J. T. Robinson, J. S. Burgess, C. E. Junkermeier, S. C. Badescu, T. L. Reinecke, F. K. Perkins, M. K. Zalalutdniov, J. W. Baldwin, J. C. Culbertson, P. E. Sheehan, and E. S. Snow, Nano Letters 10, 3001 (2010)
³¹ W.-K. Lee, J. T. Robinson, D. Gunlycke, R. R. Stine, C. R. Tamanaha, W. P. King, and P. E. Sheehan, Nano_Letters 11, 5461 (2011)
³² C. Tang, Y. Bando, Y. Huang, S. Yue, C. Gu, F. Xu, and D. Golberg, J. Am. Chem. Soc. 127, 6552 (2005)
³³ Y. Xue, Q. Liu, G. He, K. Xu, L. Jiang, X. Hu, and J. Hu, Nanoscale Res. Lett. 8, 49 (2013)
³⁴ S. M. Nakhmanson, A. Calzolari, V. Meunier, J. Bernholc, and M. Buongiomo Nardelli, Phys. Rev. B 67, 235406 (2003)
³⁵ A. R. Akhmerov and C. W. J. Beenakker, Phys. Rev. B 77, 085423 (2008)
³⁶ P. Giannozzi et al., J. Phys. Condens. Matter 21, 395502 (2009)
³⁷ J. P. Perdew, K. Burke, and M. Ernzerhof, Phys. Rev. Lett. 77, 3865 (1996)
³⁸ D. Vanderbilt, Phys. Rev. B 41, 7892 (1990)
³⁹ H. J. Monkhorst and J. D. Pack, Phys. Rev. B 13, 5188 (1976)
⁴⁰ N. Marzari, D. Vanderbilt, A. De Vita, and M. C. Payne, Phys. Rev. Lett. 82, 3296 (1999)
⁴¹ A. A. Mostofi, J. R. Yates, Y.-S. Lee, I. Souza, D. Vanderbilt, and N. Marzari, Computer Physics_Communications 178, 685 (2008)
⁴² M. Stengel, Phys. Rev. B 84, 205432 (2011)
⁴³ In addition, the apparent ambiguity in the choice of the lattice vector R in equation (2) can be lifted by properly assigning each Wannier function to a given ion according to the crystal termination⁴².

### Supplementary Material 1

### Effects of Termination in Nanoribbons

Whenever a honeycomb crystal supports a finite formal polarization, a polar discontinuity arises when the system is cut into a finite-width nanoribbon. We thus expect a finite electric field to be present as a result of the polarization charge density λ_{P} that appears at the edges. This electric field will in turn trigger a metal-insulator transition with increasing width of the nanoribbon. On the other hand, depending on the specific termination of the nanoribbon, we may have additional bound charges at the edges that partially screen the polarization charge. These contribute to the total charge density λ_{E} at each edge with a integer multiple of e per unit length. According to equation 2 above, the total charge density at the edge for a zigzag nanoribbon reads

$${λ}_{E} = \frac{e}{a} ( \frac{m}{3} + n ) . \qquad ( S1 )$$

As we mentioned above, the integer mε{0, 1, 2} is completely determined by the bulk properties of the system, while the integer n depends on the specific termination of the nanoribbon (see FIG. 4 for two possible terminations of a nanoribbon). We thus see that whenever m≠0 a non-vanishing bound charge (and the corresponding electric field) will always be present at the edges irrespective of the termination, although it may change sign depending on the value of n. Indeed, the polarization charge in these cases is fractional and thus can not be completely screened by an integral termination-induced edge charge. This is shown in FIG. 5a where we show the macroscopic average (black lines) on top of the planar average (gray lines) of the electrostatic potential energy across a ZnO nanoribbon (including also a region of vacuum on both sides of the ribbon). Solid and dashed lines refer to ribbons with unpassivated and hydrogen-terminated dangling bonds at the edges, respectively. We see that the electric field associated with the polarization charges is always different from zero in both cases, although it changes sign as the polarization charge goes from λ_{E}=−2e/(3a) (i.e. m=1, n=−1) for unpassivated edge bonds to λ_{E}=e/(3a) (i.e. m=1, n=0) for an hydrogen-terminated bonds. On the contrary, when m=0 the total charge at the edge (and consequently also the corresponding electric field) might vanish depending on the nanoribbon termination. Indeed, FIG. 5b shows that for BN nanoribbons (m=0, see Table I) an electric field is present when edge bonds are unpassivated (solid lines, λ_{E}=−e/a, i.e. n=−1) while it disappears when bonds are saturated with hydrogen (dashed lines, λ_{E}=0, i.e. n=0). To summarize, in nanoribbons made of materials for which m≠0 in equation (2) the polarization charge can not be completely screened irrespective of the edge termination and thus a finite electric field is always present, which induces a metallic state for sufficiently large widths. Nanoribbons with m=0 might still support a finite electric field but would be more susceptible to termination-induced effects.

FIG. 4 illustrates possible nanoribbon terminations, comparing a nanoribbon with unpassivated dangling bonds at the edges (FIG. 4(a)) and a nanoribbon with edge bonds saturated with hydrogen atoms (FIG. 4(b)).

FIG. 5 illustrates the macroscopic average (black lines) on top of the planar average (gray lines) of the electrostatic potential energy as a function of the in-plane coordinate orthogonal to the nanoribbon edges. Results are reported for a theoretically postulated zinc oxide 2D hexagonal crystal (ZnO, FIG. 5(a)) and boron nitride (BN, FIG. 5(b)). Solid and dashed lines refer to ribbons with unpassivated and hydrogen-terminated dangling bonds, respectively. An electric field is present in materials like ZnO, which have m≠0 in equation (2), irrespective of the edge termination.

### Wannier Functions of Group-VI Transition Metal Dichalcogenides

In order to compute the bulk formal polarization of group-VI transition metal dichalcogenides like MoS₂ we need the centers of the Wannier functions associated with the valence bands. Including the deepest electronic states into the ionic cores, we are left with six electrons in the outermost d-orbitals of the transition metal and four p-electrons for each chalcogen¹. These atomic orbitals give rise to the eleven bands shown in FIG. 6a. Seven of them are fully occupied (valence bands) and separated from the lowest four conduction bands by a direct energy gap at the Brillouin zone corners. Here and in the following we focus on the representative case of MoS₂ although similar conclusions can be drawn for other isoelectronic compounds like MoSe₂ or WS₂. A standard maximal localization procedure² allows us to associate the six lowest valence bands with as many Wannier functions that are localized on sulphur atoms with lobes pointing towards one of the nearest neighbors (see also FIG. 2c). As shown in FIG. 6b, such Wannier functions arise from the hybridization between p-orbitals on sulphur and d-orbitals on molybdenum. Less trivial is the topmost valence band, which is disentangled from the others. A careful analysis shows that this isolated band can be mapped into a rather broad Wannier function with a dominant d-character, located at the center of the hexagonal unit cell (see FIG. 2d above). As a measure of the reliability of these Wannier functions we show in FIG. 6 that a Wannier interpolation procedure is able to reproduce precisely the first-principles valence band structure. In addition, by applying equation (3), it is possible to prove that m=1 for MoS₂ (and similarly for all other group-VI transition metal dichalcogenides).

FIG. 6 illustrates the band structure and Wannier functions of MoS₂. FIG. 6(a) shows MoS₂ band structure along a path in reciprocal space connecting the high-symmetry points Γ-M-K-Γ. Solid lines: original valence and conduction bands generated directly from a DFT calculation. The dashed line separates valence bands from conduction bands. Gray circles: Wannier-interpolated valence bands. The isolated top valence band is associated with the Wannier function shown in FIG. 2(d) above. The lower six valence bands can be mapped into maximally localized Wannier functions that are symmetrically equivalent to the one in FIG. 6(b) and show strong hybridization between sulphur p-orbitals and molybdenum d-orbitals.

### Conformers of Functionalized Honeycomb Lattices

As we mentioned previously, selective functionalization of a parent heteroatomic honeycomb crystal (like BN) introduces a polar discontinuity in the system. We focused in particular on covalent hydrogenation or fluorination, when H or F atoms are adsorbed on both sides of the honeycomb lattice similarly to what happens in graphane and fluorographene. Several configurations are possible, depending on the pattern formed by the adsorbed atoms above and below the 2D sheet. Taking boron nitride as parent honeycomb lattice, FIG. 7 shows the configurations compatible with an eight-atom unit cell: (a) chair, (b) boat, and (c) stirrup^{3,4}. By projecting the atomic positions in plane, we notice that their 2D spatial group (wallpaper group) is different, being cm for boat and stirrup isomers while p3m1 for the chair structure. According to Ref 5 the chair configuration is the only one compatible with a quantized (topological) polarization [see equation (2)]. For the other conformers, instead, symmetry only constrains one component of the in-plane polarization vector, leaving the other one completely undetermined. Even though in principle the chair configuration could seem to be optimal since it ensures a stable (topological) polarization, the strain arising from the lattice mismatch between pristine and functionalized forms breaks the symmetries that protect quantization. In addition, we shall see that all conformers support a different polarization with respect to the parent material and thus give rise to a polar discontinuity. For these reasons, the chair configuration has been discussed as a reference above only for the sake of simplicity since it shares the same (2D) symmetry of the parent material and thus its bulk polarization can be expressed through equation (2).

FIG. 7 illustrates possible conformers of functionalized honeycomb lattices. Top and lateral views of the three possible configurations of hydrogenated boron nitride that are compatible with a eight-atom unit cell: chair FIG. 7(a), boat FIG. 7(b), and stirrup FIG. 7(c). A gray rectangle highlights the eight-atom unit cell adopted in the calculations. The bottom panels show a magnified perspective view of each unit cell in which the Wannier function centers are also reported as small light gray spheres. In all panels boron atoms are depicted in dark gray, nitrogen atoms in light gray, and hydrogen atoms in black;

For the purpose of engineering a polar discontinuity, all configurations are in principle equally relevant and one needs to assess their relative stability. In Table II we focus on boron nitride and we report the ground-state, binding, and formation energies (per atom) of the three configurations for both hydrogenated and fluorinated structures. The binding energy is defined as

E_{b}=E_{g}−Eₚ−N_{X}E_{X}, (S2)

while the formation energy reads

$${E}_{f} = {E}_{g} - {E}_{p} - \frac{{N}_{X}}{2} {E}_{{X}_{2}} . \qquad ( S3 )$$

In equations (S2) and (S3), E_{g} is the total energy of functionalized BN in its optimized geometry, Eₚ the total energy of the parent BN sheet, N_{X} the number of H or F atoms, and E_{X} (E_{X}_{₂}) their atomic (molecular) total energy. A negative binding (formation) energy reveals if the functionalization is likely a favorable process in the presence of the adsorbate in atomic (molecular) form. We immediately notice that for hydrogenated BN the chair configuration not only has a positive binding energy, but it is even less stable than the boat and stirrup isomers. This is in agreement with previous results on a similar level of theory^{6,7,8,9}. On the contrary, for fluorinated BN the repulsion between fluorine atoms favors a situation in which neighboring F atoms are on opposite sides of the BN sheet. As a consequence, the chair configuration is the most stable, with both the formation and binding energies being negative. Since functionalization is typically performed in atomic atmosphere, our results suggest that both fluorination and hydrogenation are achievable for BN. Although these results based on equations (S2) and (S3) are valid only in the limit of zero temperature, we have verified that our conclusions do not change even at standard ambient temperature and pressure conditions. Indeed, by replacing in equations (S2-S3) the total atomic or molecular energy with the chemical potential of the gas (including translational, rotational, vibrational, and nuclear contributions), the gain in formation (free) energy reported in Table II decreases by less than 0.3 eV/atom.

TABLE II
Ground-state (E_{g}), formation (E_{f}), and binding (E_{b}) energy
of hydrogenated and fluorinated BN in different configurations
(chair, boat, stirrup). For H functionalization the stirrup
conformer is the most stable, while in the case of fluorination
the chair configuration is preferred. A negative formation
energy in all cases suggests that fluorination and hydrogenation
should be achievable in atomic atmosphere.

| | | E_{g} (eV/atom) | E_{f} (eV/atom) | E_{b} (eV/atom) |
|---|---|---|---|---|
| H | chair | −98.533 | 0.102 | −1.032 |
| | boat | −98.551 | 0.084 | −1.050 |
| | stirrup | −98.573 | 0.062 | −1.072 |
| F | chair | −427.471 | −0.645 | −1.354 |
| | boat | −427.415 | −0.589 | −1.298 |
| | stirrup | −427.441 | −0.615 | −1.324 |

We now want to verify that a polar discontinuity between pristine and functionalized honeycomb lattices arises irrespectively of the specific configuration (chair, boat, or stirrup) of the adsorbed atoms. In order to compute the bulk formal polarization, we need the Wannier function centers for each conformer. These are shown in FIG. 7 in the case of hydrogenated BN. We notice that the three configurations are qualitatively very similar: In each unit cell we find a Wannier function centered approximately mid-bond between each H and N or B atoms and other three around each anion (N in this case) along directions pointing towards its nearest B neighbors. For the chair conformer, this is in agreement with the schematic picture in FIG. 5b. Thus, only minor quantitative variations occur between the conformers, while more radical qualitative features distinguish them from pristine BN as already mentioned previously (see FIGS. 2a and b). In particular the formal polarization is always orthogonal to the zigzag direction and reads (in units of e/Å): −0.257 (chair), −0.288 (boat), −0.202 (stirrup), and −0.398 (pristine BN). Although piezoelectric contributions should be taken into account when considering interfaces, this analysis already shows that for any conformer selective hydrogenation leads to a polar discontinuity in BN honeycomb lattices. Indeed, we have verified (through a more careful simulation of a zigzag interface between pristine and functionalized BN) that free charges appear at the boundaries as a result of the polarization-induced electric fields independently of the specific arrangement (chair, boat, or stirrup) of hydrogen atoms.

### REFERENCES 2

¹ S. Lebègue and O. Eriksson, Phys. Rev. B 79, 115409 (2009)
² N. Marzari, A. A. Mostofi, J. R. Yates, I. Souza, and D. Vanderbilt, Rev. Mod. Phys. 84, 1419 (2012)
³ J. O. Sofo, A. S. Chaudhari, and G. D. Barber, Phys. Rev. B 75, 153401 (2007)
⁴ A. Bhattacharya, S. Bhattacharya, C. Majumder, and G. P. Das, Phys. Rev. B 83, 033404 (2011)
⁵ P. Jadaun, D. Xiao, Q. Niu, and S. K. Banerjee, Phys. Rev. B 88, 085110 (2013)
⁶ F. W. Averill, J. R. Morris, and V. R. Cooper, Phys. Rev. B 80, 195411 (2009)
⁷ Y. Wang and S. Shi, Solid State Commun. 150, 1473 (2010)
⁸ A. Bhattacharya, S. Bhattacharya, C. Majumder, and G. P. Das, Phys. Stat. Sol. (RRL) 4, 368 (2010)
⁹ D. K. Samarakoon and X.-Q. Wang, Appl. Plays. Lett. 100, 103107 (2012)

### Supplementary Material 2

Exemplary processing techniques that may be adopted in the processing phase in order to realize the kind of nanostructures or heterostructures described above, together with some possible examples of devices and device applications of the present invention are now described.

FIG. 8 illustrates an example of a device D1 according to the present invention including a 1D channel of free carriers at the interface I1 between two insulating materials with different polarization exploited to transfer a current signal from one device (device 1) to another (device to 2), exceeding the current limits of lithography. The device D1 can include an electrical connector to connect the 1D channel to Device 1, and an electrical connector to connect the 1D channel to Device 2. In the present example, the device D1 comprises a two-dimensional component or element including a first two-dimensional insulating material (Material 1) and a second two-dimensional insulating material (Material 2) as well as a polar discontinuity of electric polarization formed at an interface between Material 1 and Material 2.

A polar discontinuity is located, for example, at a line boundary at the interface between two insulating materials with different polarization.

Alternatively, the present invention relates to a reconfigurable switch. The device D1 comprises a two-dimensional component or element including a two-dimensional insulating material and a polar discontinuity generator (for example, the mechanical switch, thermal switch, electrical switch or laser-driven defunctionalization described below) to dynamically generate or dynamically and reversibly generate one or more polar discontinuities of the electric polarization in the two-dimensional insulating material. Thus, any device amongst a first plurality of devices can be dynamically electrically connected in real-time to any other device amongst a second plurality of devices, the first and second plurality of devices being interconnected directly or indirectly via the two-dimensional insulating material.

Alternatively, the device D1 of FIG. 8 can further include such a polar discontinuity generator in addition to the polar discontinuity of interface I1. This would allow DEVICE 1 and/or DEVICE 2 to be electrically connected to other devices interconnected via material 1 or material 2.

FIG. 9 illustrates an example of devices D2 and D3 according to the present invention including three possible polarization states in, for example, honeycomb materials that allow the realization of more sophisticated geometries like junctions where a single channel is split into two in order to connect multiple devices (FIG. 9(a)).

FIG. 9(b) shows how a third material can be used to define a central region. If a magnetic field pierces this region, the interference between the currents flowing in the two arms (to the left and to the right of material 3) can be used to detect and measure the magnetic field.

In the present example, the devices D2 and D3 comprise a two-dimensional component or element including a first two-dimensional insulating material (Mat. 1), a second two-dimensional insulating material (Mat. 2) and a third two-dimensional insulating material (Mat. 3) as well as a polar discontinuity of electric polarization formed at interfaces 12, 13, 14 between materials.

Devices D2 and D3 can also include electrical connectors to connect 1D channels to Devices A, B and C.

FIG. 10 is a schematic representation of the possible applications of the present invention in solar energy harvesting. When light is shined onto the device, it can be absorbed in the insulating bulk of the materials thus creating an electron hole pair. The built-in electric field associated with the polarization charges at the interfaces between materials can then split the electron and the hole and drive them towards opposite interfaces 15, 16. Here the electron and the hole can be collected through the 1D charge channels and create a bias that can be adopted to power an external device.

In the present example, device D4 comprises a two-dimensional component or element including a first two-dimensional insulating material (Mat. 1), a second two-dimensional insulating material (Mat. 2) and a third two-dimensional insulating material (Mat. 3) as well as a polar discontinuity of electric polarization formed at interface IS between material Mat.1 and material Mat.2 and at interface 16 between material Mat.2 and material Mat.3. Please note the device works even if the materials Mat.1 and Mat.3 are the same.

The device D4 can also include electrical connectors to connect the 1D channels to an external device to provide the generated energy to the external device.

### Processing

Here we describe methods to provide sharp and atomically abrupt interfaces along a well-specified direction, which is important to achieve a good device quality.
Nanoribbons
   Tailoring 2D materials into nanoribbons: ribbons can be obtained from their parent 2D precursors by hydrogen etching [Yang2010] or by electron beam-initiated mechanical rupture [Kim2013]. The atomic sharpness and edge quality has been demonstrated for graphene and these techniques seem very promising for all 2D materials.
   Unzipping of nanotubes: in order to realize well-defined ribbons with sharp interfaces, one of the most effective methods could be the longitudinal unzipping of nanotubes, as described for instance in [Kosynskin2009]
   Self-assembly of regular nanoribbons: narrow and atomically precise graphene nanoribbons have been realized [Cai2010] using a bottom-up growth technique by means of assisted polymerization of molecular precursors. An analogous technique (by choosing proper molecular precursors) may be used to grow precise nanoribbons of materials beyond graphene, and in particular those described in this invention.
Phase-engineered interfaces
   Lateral heteroepitaxy: lateral interfaces between 2D transition metal dichalcogenides have been realized by changing the molecular source during growth of the crystal, i.e. proving a different transition metal [Gong2014, Huang2014] or a different chalcogen atom [Duan2014]. Similar techniques could be adopted to realize interfaces between group-IV and group-VI transition metal dichalcogenides.
   Mechanical switch: the different arrangement of the chalcogen atoms in the 1T and 2H crystal phases gives rise to a different response to an external vertical pressure, e.g. exerted by a STM tip (nanoindentation). Indeed, in the 2H phase, the two layers of chalcogen atoms are identical and lie on top of each other, so that they strongly repel when subject to a vertical pressure. On the contrary, in the 1T phase the two layers are displaced, so that they are less sensitive to external pressures thus making the 1T more favorable than the 2H phase at sufficiently high pressures. The local application of an external pressure (through for instance nanoindentation) on a selected area of a sample in the 2H phase should induce a phase transition, converting that region to the 1T phase. At the boundary between the two phases a polar discontinuity appears as described above.
   Electrical switch: the different symmetry between the 1T and 2H phase leads to a different response to an external electric field. This means in particular that a sufficiently large electric field might induce a symmetry breaking from the 1T to the 2H phase. A finite electric field applied locally to a selected portion of a sample in the 1T phase should convert it to the 2H phase. At the boundary between the two phases a polar discontinuity appears as described above.
   Thermal switch: a local increase in temperature (realized for instance using a focused laser beam) might trigger a phase transition between the different phases of transition metal dichalcogenides with the possibility to introduce phase boundaries.
Selective functionalization
   Laser-driven defunctionalization: In order to achieve a precise selective functionalization, the host 2D lattice may be completely functionalized with the chosen adsorbed atoms (H or F, for instance), and then a focused laser beam may be shined onto the region that should be pristine, with an energy of the beam large enough to drive the desorption of the adsorbed atoms, but not too strong in order to avoid the decomposition of the host lattice
   Lithography: lithographic methods may be used to first mask the regions of the device that should not be functionalized, and then functionalizing the layer. The photomask will effectively avoid the functionalization of the covered region, while the unprotected regions will adsorb the functionalizing atoms. In a final step, the photomask is removed.
Completely or Fully functionalized graphene-BN heterostructures: very recently, atomically-sharp interfaces between graphene and BN have been realized [Sutter2012, Liu2014]. While the graphene-BN system is not suitable to realize a polar discontinuity (because graphene is not an insulator), a complete or full functionalization of both graphene and BN would provide a very effective material platform for the devices of the present invention. Once the graphene-BN heterostructure is realized, standard techniques used to functionalize graphene (obtaining graphane [Elias2009] or fluoro-graphene [Nair2010]) can be used on the whole system, to functionalize both materials. In this way a polar discontinuity arises according to the present invention.
Transition metal dichalcogenides nanoribbons: standard techniques as the ones described above to realize nanoribbons in sp materials (2D materials tailoring, nanotube unzipping, etc.) may be used also to produce nanoribbons composed of transitions metal dichalcogenides.

### Applications and Devices

Nanoelectronics
   Conductive electrical wires between 2D devices: The 1D channels that form at an interface between two 2-dimensional insulating materials may be used to connect different devices (Device 1, Device 2) integrated onto the otherwise insulating 2D platform. This gives the opportunity to realize atomically-thin conductors, much below the current limits of lithography for standard electronic devices. See for instance FIG. 8 for a schematic illustration of this aspect of the present invention. The two materials (Material 1, Material 2) facing at the interface (and forming the interface I1) can be for instance boron nitride and hydrogenated boron nitride, and their widths W1, W2 should be in a range that allows the presence of metallic states at the boundary (at least few tens of nanometers, i.e. for example W1>10 nm and preferably 10 nm<W1≦100 nm; and W2>10 nm and preferably 10 nm<W2≦100 nm). We note that the structure can be even repeated periodically (i.e, Mat.1-Mat. 2-Mat. 1-Mat. 2 etc.) in order to obtain several wires that connect different devices.
   Spintronic devices: the conductive electron and hole channels at an interface turn out to be spin-polarized in most material platforms. This means that spintronic devices (where the quantity that is transported is the spin of the electrons, rather than the electron charge, allowing not only to realize novel devices, but also to significantly reduce the energy required for the device operation) can be realized, with a platform analogous to the one already described (FIG. 8).
   Junctions: As we have extensively described above, in 2D honeycomb materials three different choices exist for the value of the material polarization. This offers the possibility of defining junctions at which the wire (1D channel) splits into two channels that then connect different devices (see FIG. 9a). This could be realized for instance using interfaces between group-VI (material 1 in FIG. 9a) and group-IV (material 2 in FIG. 9a) transition metal dichalcogenides in their stable phase (2H and 1T, respectively), where part of the second material close to the interface (denoted material 3 in FIG. 9a) is brought into the 2H phase. As an example we can consider Material 1 to be MoS₂ in the 2H phase, Material 2 to be ZrS₂ in the 1T phase and Material 3 to be ZrS₂ in the 2H phase. The width of each material should be at least few tens of nanometers. For example, W1>20 nm and preferably 20 nm<W1≦100 nm; W2>20 nm and preferably 20 nm<W2≦100 nm; W3>10 nm and preferably 10 nm<W3≦50 nm; W4>10 nm and preferably 10 nm<W4≦50 nm; and W5>10 nm and preferably 10 nm<W5≦50 nm. This shows an effective way to split the electronic channel into two branches, allowing signals to be sent to different devices (from Dev.A to Dev.B and Dev.C). In addition, it could be possible to design geometric regions as those shown in FIG. 9b using for instance the same set of materials as for FIG. 9a. This kind of geometry may prove extremely effective for magnetic field detectors and interferometers, as discussed in the following point.
   Magnetic field detectors and interferometers: If a magnetic field has a non-zero flux through the surface defined by the central region (Mat.3) in FIG. 9b, interference effects appear changing the value of the current that can flow through the device (Aharanov-Bohm effect). For large areas of the central region, the electric current oscillates rapidly as a function of the magnetic field, providing a way to realize very sensitive interferometers that are able to detect tiny variations of the magnetic field. Advantageously according to the present invention, it is also feasible to realize extremely small sizes of the central region, which in turn allows having a single current oscillation over a large range of magnetic fields (for instance, a 10 nm×10 nm region allows to uniquely measure magnetic fields up to 3 tesla (for example, W4=10 nm)). This in turn allows making transparent, flexible, ultrathin detectors or interferometers for the magnetic field which could for instance be embedded on the surface of other devices or displays, also as a way to interact with the device besides being a measuring tool.
Solar-energy harvesting devices: when a photon is absorbed by the material Mat.2, it creates an electron-hole pair, known as an exciton. The electric fields embedded in the system can effectively split the electron-hole pair, moving them to two different channels, and this in turn creates a bias that can be used to power devices, as schematically depicted in FIG. 10. We also emphasize that the effective wavelength at which the device is sensitive depends not only on the bandgap of the materials (Mat.2), but also on the device size (the distance Dt between the two interfaces 15 and 16), since for large excitons the effective exciton absorption energy can be reduced due to the band bending caused by the intrinsic electric field. This increases the efficiency of the device D4 and could be exploited to achieve even better results by integrating into a single device many systems (a plurality of devices D4) with different widths (Dt) or comprising different materials (Mat.2). Nonetheless, we recall that in order to have a sizable electric field inside the sample, the distance Dt between the two interfaces in FIG. 10 should be at most a few tens of nanometers. For example, 1 nm<Dt≦10 nm. This could be realized for instance using interfaces between pristine BN (material 1 and material 3 in FIG. 10) and functionalized BN (material 2 in FIG. 10) or any other pair of materials with different polarization. We also emphasize that material 1 and material 3 can be substituted by vacuum.

### REFERENCES 3

[Cai2010] J. Cai et al., Nature 466, 470 (2010)
[Duan2014] X. Duan et al., Nature Nanotech. 9, 1024 (2014)
[Elias2009] D. C. Elias et al., Science 323, 610 (2009)
[Gong2014] Y. Gong et al., Nature Materials 13, 1135 (2014)
[Huang2014] C. Huang et al., Nature Materials 13, 1096 (2014)
[Kim2013] K. Kim et al., Nat. Commun. 4, 2723 (2013)
[Kosynkin2009] D. V. Kosynkin et al., Nature 458, 872 (2009)
[Liu2014] L. Liu et al., Science 343, 163 (2014)
[Niar2010] R. R. Niar et al., Small 6, 2877 (2010)
[Sutter2012] P. Sutter et al., Nano Lett. 12, 4869 (2012)
[Yang2010] R. Yang et al., Adv. Mat. 22, 4014 (2010)

Having described now the preferred embodiments of this invention, it will be apparent to one of skill in the art that other embodiments incorporating its concept may be used. This invention should not be limited to the disclosed embodiments, but rather should be limited only by the scope of the appended claims.

1. Device comprising a two-dimensional component, the two-dimensional component including at least one two-dimensional insulating material and a polar discontinuity of electric polarization.

2. Device according to claim 1, wherein the at least one two-dimensional material is of honeycomb structure.

3. Device according to claim 1, including a line boundary at which the polar discontinuity is located.

4. Device according to claim 1, wherein a width of the at least one two-dimensional material is such that a finite electric field is present as a consequence of the polar discontinuity.

5. Device according to claim 1, wherein a width of the at least one two-dimensional material is such that a insulator-to-metal transition has occurred as a consequence of the polar discontinuity.

6. Device according to claim 1, wherein the at least one two-dimensional material is at least partially functionalized, fully functionalized or selectively functionalized.

7. Device according to claim 1, wherein the two-dimensional component is or includes a finite width nanoribbon.

8. Device according to claim 1, wherein the two-dimensional component is or includes a monolithic two-dimensional insulating material; or is formed of or includes at least two different two-dimensional insulating materials.

9. Device according to claim 1, wherein the monolithic two-dimensional insulating material is surrounded by a vacuum, or the at least two different two-dimensional insulating materials are surrounded by a vacuum.

10. Device according to claim 1, wherein the two-dimensional component is formed of or includes at least two different two-dimensional insulating materials that are joined at the two-dimensional material edges to form a lateral heterostructure.

11. Device according to claim 1, wherein the two-dimensional component comprises functionalized boron nitride and/or functionalized graphene.

12. Device according to claim 1, including at least two 2-dimensional insulating materials, each having a different crystal phases and distinct electric polarizations so that an interface between the at least two 2-dimensional insulating materials provides a polar discontinuity.

13. Device according to claim 1 wherein the device is a nanotube.

14. Electronic circuit, electronic device, spintronic device, solar energy device, solar cell, magnetic field detector or interferometer including the device according to claim 1.

15. Device according to claim 1, including a first 2-dimensional insulating material for absorbing incident electromagnetic radiation, the first 2-dimensional insulating material being sandwiched between a second 2-dimensional insulating material or sandwiched between a second and third 2-dimensional insulating material.

16. Solar energy device or solar cell including a plurality of devices according to claim 15, the plurality of devices including a first and a second device; the first device including a first 2-dimensional insulating material having a different width and/or different material to that of a first 2-dimensional insulating material of the second device to increase the efficiency of the solar energy device or solar cell.

17. Method of producing a device according to claim 1, including the steps of:
providing a two-dimensional component including at least one two-dimensional insulating material; and
surrounding the two-dimensional component by a vacuum to generate a polar discontinuity.

18. Method according to claim 17, wherein the two-dimensional component is or includes a monolithic material, or is formed of or includes at least two different materials.

19. Method of producing a device according to claim 1, including the steps of:
providing a two-dimensional insulating material; and
partially, fully or selectively functionalizing the two-dimensional insulating material to generate a polar discontinuity.

20. Method according to claim 17, wherein the two-dimensional material is a finite width nanoribbon of honeycomb structure.

21. Method according to claim 19, wherein the two-dimensional component is formed of or includes at least two different materials.

22. Method of producing a device according to claim 1, including the steps of:
providing a first 2-dimensional insulating material having a first crystal phase and a distinct electric polarization; and
providing a second 2-dimensional insulating material having a second crystal phase and a distinct electric polarization, the second 2-dimensional insulating material being in contact with the first 2-dimensional insulating material to form an interface between the two 2-dimensional insulating materials and a polar discontinuity.

23. Method according to claim 22, wherein the first and second crystal phases are identical and the chemical composition of the first 2-dimensional insulating material is different to that of the second 2-dimensional insulating material; or wherein the first and second crystal phases are non-identical and the chemical composition of the first 2-dimensional insulating material is the same as that of the second 2-dimensional insulating material.

24. Device according to claim 1, wherein the two-dimensional material is not AlN, ZnO or SiC in their pristine unfunctionalized monolayer form.

25. Device including a two-dimensional component, the two-dimensional component including at least one two-dimensional insulating material and a polar discontinuity of the electric polarization, wherein the device is obtained according to the method of claim 17.
